(19) United States
(12) Patent Application Publication
(10) Pub. No.: US 2006/0091453 A1
(43) Pub. Date: May 4, 2006

(54) Trench MIS device and method for manufacturing trench MIS device

(75) Inventors: Noboru Matsuda, Kanagawa (JP); Koichi Takahashi, Fukuoka (JP); Keiko Kawamura, Kanagawa (JP); Masanobu Tsuchitani, Kanagawa (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: KABUSHIKI KAISHA TOSHIBA, Tokyo (JP)

(21) Appl. No.: 11/208,619

(22) Filed: Aug. 23, 2005

(30) Foreign Application Priority Data
Aug. 26, 2004 (JP) 2004-246887

(51) Int. Cl. H01L 29/94

(52) U.S. Cl. 257/330

(57) ABSTRACT

A trench MIS device includes a drain region, a base region disposed on the drain region, the base region having a channel face, a source region disposed on the base region, the source region having a source end face, the source end face being continuous with the channel face, a gate insulator disposed along the channel face and the source end face, a gate electrode disposed opposite to the channel face through the gate insulator, and a cavity portion provided in the drain region, the cavity portion being opposite to the gate electrode.

### CROSS REFERENCE TO RELATED APPLICATIONS AND INCORPORATION BY REFERENCE

This application is based upon and claims the benefit of priority from prior Japanese Patent Application P2004-246887 filed on Aug. 26, 2004, and the entire contents thereof are incorporated herein by reference.

### BACKGROUND OF THE INVENTION

1. Field of the Invention

The present invention relates to a semiconductor device. More specifically, the present invention relates to a trench MIS device and a method for manufacturing the trench MIS device.

2. Description of the Related Art

In recent years, MOS field-effect transistors (MOS transistor) including a trench-gate have been widely used, particularly as a power-switching device. In order to switch the power-switching device at high speed, it is needed to reduce the product of an on-state resistance (Rₒₙ) and a switching electric charge (Q_{sw}) of the transistor, each of which is an index characteristic. Here, a trench-gate MOS transistor includes a gate electrode opposite a drain region through a gate insulator. Therefore, a capacitance (C_{gd}) between the gate electrode and the drain region is established in the trench-gate MOS transistor. As a result, switching electric charge (Q_{sw}) is increased and switching characteristics of the transistors are degraded. Moreover, reducing the on-state resistance (Rₒₙ) and reducing the switching electric charge (Q_{sw}) are not incompatible, because there is a tradeoff relation between the on-state resistance (Rₒₙ) and the switching electric charge (Q_{sw}). In order to solve the above problem, a thick gate insulator is formed in the lower portion of the trench to reduce the capacitance (C_{gd}). For example, Japanese Patent Application Laid-Open No. 2002-299619 discloses a method for reducing both the capacitance (C_{gd}) and the on-state resistance (Rₒₙ). According to the method, a thick gate electrode layer and a thin gate insulator are formed in the upper portion of the trench. On the contrary, a thin gate electrode layer and a thick gate insulator are formed in the lower portion portion of the trench.

However, though the thick gate insulator is formed, the capacitance (C_{gd}) is reduced by only 20% at most. Therefore, performance characteristics have not been effectively improved in the trench-gate MOS transistor having the gate electrode opposite the drain region through the gate insulator. Further, the above problem has been encountered not only in MOS transistors but also in MIS transistors.

### SUMMARY OF THE INVENTION

An aspect of present invention inheres in a trench MIS device according to an embodiment of the present invention. The trench MIS device includes a drain region, a base region disposed on the drain region, the base region having a channel face, a source region disposed on the base region, the source region having a source end face, the source end face being continuous with the channel face, a gate insulator disposed continuously along the channel face and the source end face, a gate electrode disposed opposite to the channel face through the gate insulator, and a cavity portion provided in the drain region below the gate electrode, the cavity portion being opposite to the gate electrode.

Another aspect of present invention inheres in a method for manufacturing the trench MIS device according to an embodiment of the present invention. The method includes preparing a semiconductor substrate on which a drain region, a base region, and a source region are formed in order, forming a trench extending from the source region to the drain region via the base region, the trench having a trench sidewall and a trench bottom, forming a gate insulator on the trench sidewall and the trench bottom, forming a polycrystalline silicon film on the gate insulator, the polycrystalline silicon film being doped with a plurality of dapants, and forming a cavity portion in a lower portion of the trench and a gate electrode derived from the polycrystalline silicon film in an upper portion of the trench by a diffusion of a plurality of silicon atoms in the polycrystalline silicon film, the diffusion being caused by a hydrogen annealing of the polycrystalline silicon film.

Yet another aspect of present invention inheres in a method for manufacturing the trench MIS device according to an embodiment of the present invention. The method includes forming a drain region on a semiconductor substrate, forming a cave in the drain region, diffusing a plurality of silicon atoms inside a cave sidewall of the cave by a hydrogen annealing of the cave so as to fill an upper portion of the cave with the silicon atoms to form a cavity portion in the drain region, forming a trench above the cavity portion in the drain region, the trench being not penetrating to the cavity portion, forming a gate insulator on a trench sidewall of the trench, and forming a gate electrode on the gate insulator by filling the trench with an electrically conductive material.

### BRIEF DESCRIPTION OF DRAWINGS

FIG. 1A and FIG. 1B are cross sections showing trench MIS devices in accordance with first and second embodiments, respectively;

FIG. 2A, FIG. 2B, and FIG. 2C are sectional views of the trench MIS devices depicting the manufacturing process in accordance with the first, second, and third embodiments;

FIG. 3A, FIG. 3B, FIG. 3C, and FIG. 3D are sectional views of the trench MIS devices depicting the manufacturing process in accordance with the first embodiment;

FIG. 4A, FIG. 4B, FIG. 4C, FIG. 4D, and FIG. 4E are sectional views of the trench MIS devices depicting the manufacturing process in accordance with the second embodiment;

FIG. 5 is a cross section showing the trench MIS device in accordance with the third embodiment;

FIG. 6A, FIG. 6B, and FIG. 6C are sectional views of the trench MIS devices depicting the manufacturing process in accordance with the third embodiment;

FIG. 7 is a cross section showing trench MIS device in accordance with the fourth embodiment;

FIG. 8A, FIG. 8B, FIG. 8C, FIG. 8D, FIG. 8E, and FIG. 8F are sectional views of the trench MIS devices depicting the manufacturing process in accordance with the fourth embodiment;

FIG. 9A, FIG. 9B, FIG. 9C, FIG. 9D, FIG. 9E, and FIG. 9F are sectional views of the trench MIS devices depicting the manufacturing process in accordance with a fifth embodiment; and

FIG. 10A, FIG. 10B, and FIG. 10C are schematic drawings of gates and drains in the trench MIS device in accordance with the fifth embodiment.

### DETAILED DESCRIPTION OF THE INVENTION

Various embodiments of the present invention will be described with reference to the accompanying drawings. It is to be noted that the same or similar reference numerals are applied to the same or similar parts and elements throughout the drawings, and the description of the same or similar parts and elements will be omitted or simplified.

### First Embodiment

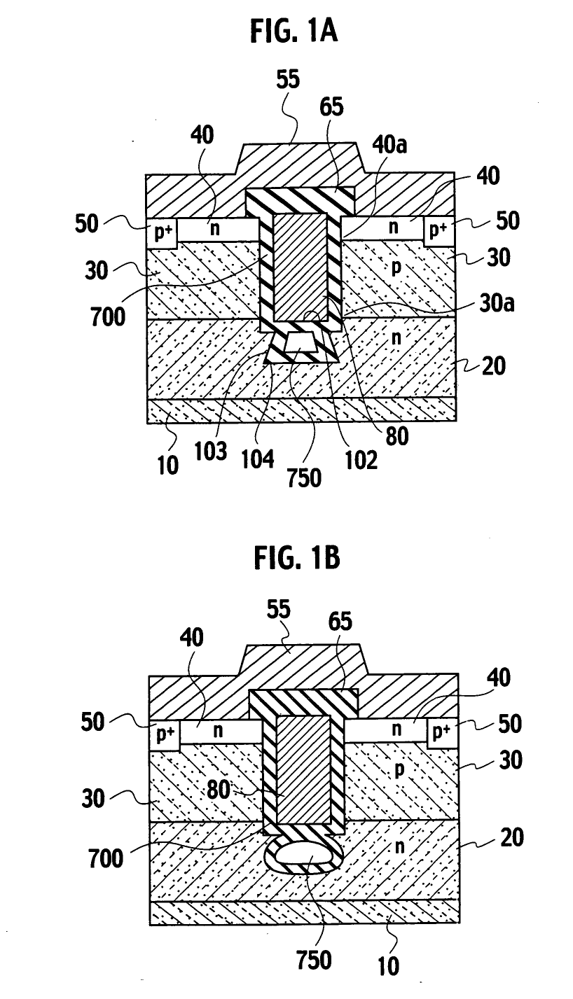

With reference to FIG. 1A, a plurality of vertical MOSFETs such as a plurality of trench MIS devices are formed on a semiconductor substrate 10. One of the trench MIS devices in accordance with the first embodiment includes a drain region 20, a base region 30 disposed on the drain region 20, the base region 20 having a channel face 30a, a source region 40 disposed on the base region 30, the source region 40 having a source end face 40a, the source end face 40a being continuous with the channel face 30a, a gate insulator 700 disposed continuously along the channel face 30a and the source end face 40a, a gate electrode 80 disposed opposite to the channel face 30a through the gate insulator 700, and a cavity portion 750 provided in the drain region 20 below the gate electrode 80, the cavity portion 750 being opposite to the gate electrode 80. Since the gate electrode 80 is disposed opposite to the channel face 30a, the gate insulator 700 is interposed between the base region 30 and the gate electrode 80.

An interlevel insulator 65 is disposed on the gate electrode 80, and a source electrode layer 55 is disposed on the source region 40 and the base contact diffusion region 50. In addition, a drain electrode, not shown in the figure, is formed on the rear surface of the semiconductor substrate 10.

In the trench MIS device according to the first embodiment, the gate insulator 700 containing silicon oxide (SiO₂), for example, extends to a portion between an upper portion of the cavity portion 750 and a electrode bottom 102 of the gate electrode 80. Also, the gate insulator 700 is disposed along a cavity inner wall such as a cavity sidewall 103 of the cavity portion 750 and a cavity bottom 104 of the cavity portion 750. The cavity portion 750 surrounded by the extended gate insulator 700 is provided in the drain region and may have an inversely tapered shape where the cavity portion 750 broadens as it goes downward within the drain region 20. For example, a sectional shape of the cavity portion 750 is trapezoidal in a direction perpendicular to the drain region 20 and a bottom base of the sectional shape is longer than an upper side of the sectional shape.

The drain region 20 and the source region 40 have a first conductivity type. On the contrary, the base region 30 has a second conductivity type. The “first conductivity type” and the “second conductivity type” are opposite to each other. When the first conductivity type is an n-type, the second conductivity type is a p-type, and if the first conductivity type is the p-type, the second conductivity type is the n-type. In the following description, an n-channel transistor is described as the trench MIS device in accordance with the first embodiment. Therefore, the first conductivity type is the n-type and the second conductivity type is the p-type. However, a p-channel transistor is also taken into account by exchanging the p-type for the n-type.

The cavity portion 750, which is an air cavity, surrounded by the gate insulator 700 is provided in the drain region 20. Therefore, compared to an earlier trench MIS device, the distance between the drain region 20 and the gate electrode 80 in a direction perpendicular to the drain region 20 is increased by the cavity portion 750. Substantially all of the increased distance between the drain region 20 and the gate electrode 80 is occupied by the cavity portion 750 of which relative dielectric constant is about 1.0. Consequently, in the trench MIS device according to the first embodiment, a capacitance (C_{gd}) between the gate electrode 80 and the drain region 20, which is located respectively above and below the cavity portion 750, can be substantially reduced. On the other hand, even thought the capacitance (C_{gd}) is reduced, the gate insulator 700 adjacent to the base region 30, which forms an inversion layer, is not substantially influenced by the increased distance between the drain region 20 and the gate electrode 80 because the cavity portion 750 is formed only in the drain region 20. The trench MIS device in accordance with the first embodiment can cancel the tradeoff relation that existed between the reducing an on-state resistance (Rₒₙ) and reducing the capacitance (C_{gd}) in the earlier device. The trench MIS device in accordance with the first embodiment can effectively reduce the capacitance (C_{gd}) by the cavity portion 750. Also, the trench MIS device in accordance with the first embodiment can reduce the on-state resistance (Rₒₙ) independent of the increase and decrease in the capacitance (C_{gd}) by adjusting the depth of the base region 30, for example. Specifically, since the relative dielectric constant of the cavity portion 750 implemented by an air cavity is less than one third of the relative dielectric constant of the gate insulator 700, the capacitance (C_{gd}) can be easily reduced to at least about half of the earlier value while the value of the on-state resistance (Rₒₙ) is suppressed.

On the basis of an extremely simplified model, examples where the capacitances (C_{gd}) are reduced are shown below.

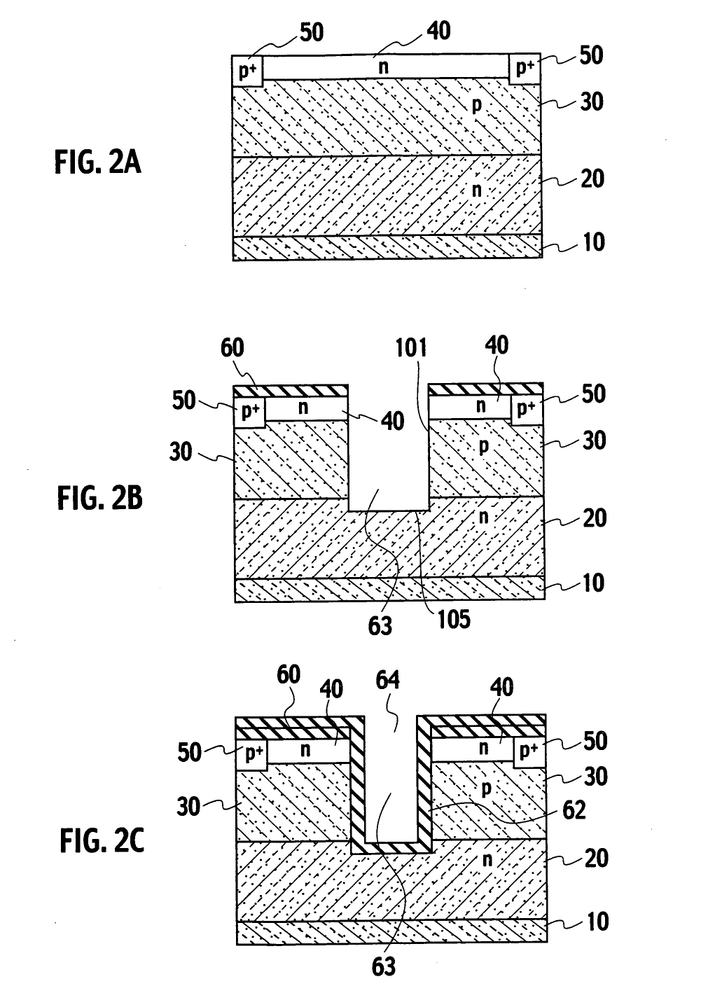

For first example, in a direction parallel to the semiconductor substrate 10, the cross sectional area of the top of the cavity portion 750 provided in the drain region 20 is two third of the cross sectional area of a trench bottom 105 shown in FIG. 2B of a trench 63 filled with the gate insulator 700 and the gate electrode 80 shown in FIG. 1A. In the direction perpendicular to the drain region 20, the height of the cavity portion 750 is equal to the thickness of the gate insulator 700. The relative dielectric constant of the gate insulator 700 is approximately 3.5. In this case, the capacitance (C_{gd}) is reduced by approximately 50% compared with the case where the cavity portion 750 is not provided in the drain region 20.

For second example, in the direction parallel to the semiconductor substrate 10, the cross sectional area of the top of the cavity portion 750 provided in the drain region 20 is equal to the cross sectional area of the trench bottom 105 of the trench 63 filled with the gate insulator 700 and the gate electrode 80. The height of the cavity portion 750 is one third of the thickness of the gate insulator 700 in the direction perpendicular to the drain region 20. The relative dielectric constant of the gate insulator 700 is approximately 3.5. In this case, the capacitance (C_{gd}) is also reduced by approximately 50% compared with the case where the cavity portion 750 is not provided in the drain region 20.

According to the first embodiment, as described above, the switching loss of transistors can be significantly reduced since the capacitance (C_{gd}) is reduced. Also, the tradeoff relation between the capacitance (C_{gd}) and the on-state resistance (Rₒₙ) that has been a problem in the earlier device is also dissolved. Therefore, the first embodiment is effective when the first embodiment is applied to a semiconductor device to be required to show high-speed switching. Further, the withstanding voltage (V_{DSS}) between the drain region 20 and the source region 40 is stabilized due to effect of the electric field relaxation.

In the trench MIS device according to the first embodiment, the on-state resistance (Rₒₙ) varies depending on an amount of protrusion of the gate electrode 80 into the drain region 20. That is because once the trench MIS device is switched on, an accumulation layer of a number of carriers (here, electrons) generates near the drain region 20 opposite to the gate electrode 80 through the gate insulator 700. Thus, an easy flow of the drain current occurs. When the amount of protrusion of the gate electrode 80 is increased, the opposing area of the drain region 20 opposite to the gate electrode 80 through the gate insulator 700 is increased. However, increase in the capacitance (C_{gd}) between the drain region 20 and the gate electrode 80 is generally accompanied with the increase of the amount of protrusion of the gate electrode 80, resulting in the increase in the switching electric charge (Q_{sw}) at the time of switching the transistor. Therefore, the amount of protrusion of the gate electrode 80 into the drain region 20 has a contradictory effect on the capacitance (C_{gd}) and the on-state resistance (Rₒₙ) respectively. For designing the trench MIS device, adjustment between the reduction effect of the on-state resistance (Rₒₙ) and the reduction effect of the capacitance (C_{gd}) can be provided by using the amount of protrusion of the gate electrode 80 as a parameter.

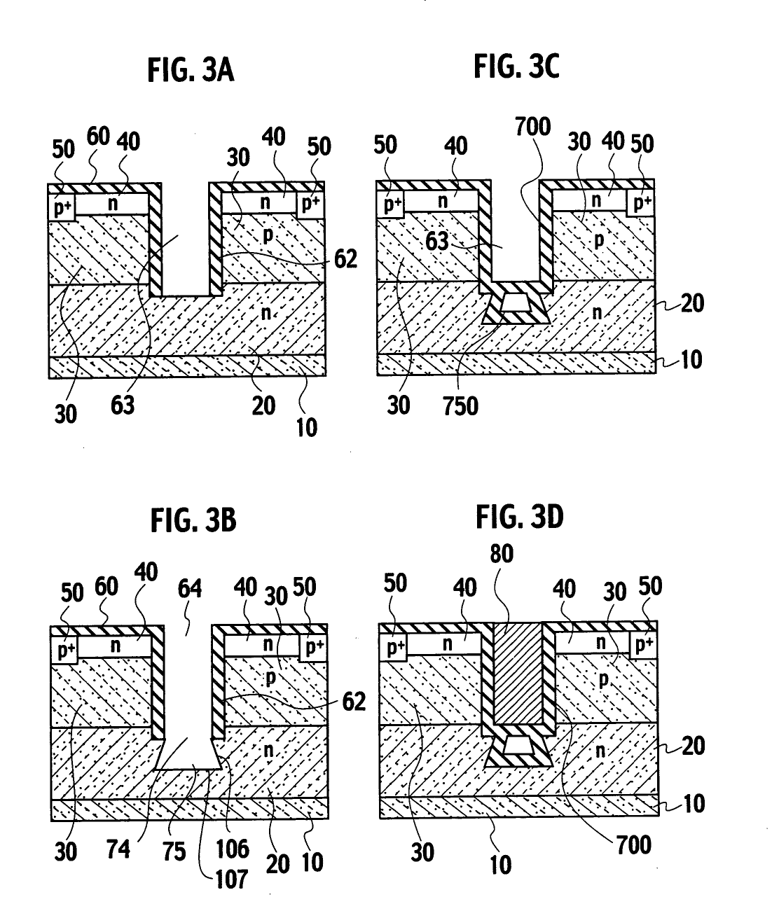

With reference to FIGS. 2A-2C and FIGS. 3A-3D, a method for manufacturing the trench MIS device in accordance with the first embodiment is described. For example, the method for manufacturing the trench MIS device includes preparing the semiconductor substrate 10 on which the drain region 20, the base region 30, and the source region 40 are formed in order, forming the trench 63 extending to the drain region 20 through the source region 40 and the base region 30, etching selectively a portion of the drain region 20 exposed to the trench 63 to form the cave 75 under the trench 63, forming the gate insulator 700 on a trench sidewall 101 of the trench 63 and the cave sidewall 106 of the cave 75 to isolate the trench 63 from the cave 75 with the gate insulator 700, and filling the trench 63 with an electrically conductive material to form the gate electrode 80.

In the following, an example of the method for manufacturing the n-channel transistor is described.

In FIG. 2A, the semiconductor substrate 10 on which the n-type drain region 20, the p-type base region 30, and the n-type source region 40 is formed is prepared. The drain region 20 is an epitaxial layer grown by epitaxial growth on the semiconductor substrate 10, for example. The p-type base region 30 is formed by doping a plurality of dopants such as boron ions (B⁺), which provide the p-type conductivity, into a surface side of the epitaxial layer.

As shown in FIG. 2A, the source region 40 is selectively formed together with the p⁺-type base contact diffusion region 50 on the base region 30. For that purpose, for example, a silicon oxide film (not shown) is formed on the surface of the base region 30 and then the silicon oxide film is selectively etched. Thereafter, by using the etched silicon oxide film as a doping mask, the dopants that provide conductivity types are selectively doped into the base region 30 to form the source region 40 and the base contact diffusion region 50.

In FIG. 2B, the silicon oxide film 60 is deposited on the surfaces of the source region 40 and the base contact diffusion region 50 by a chemical vapor deposition (CVD) process. Then, the silicon oxide film 60 is selectively and anisotropically etched. Thereafter, the source region 40, the base region 30, and the drain region 20 are selectively etched by a reactive ion etching (RIE), for example. Here, the etched silicon oxide film 60 is used as an etching mask. Thus, as shown in FIG. 2B, the trench 63 is formed. The trench 63 extends through the source region 40 and the base region 30 down to the drain region 20.

In FIG. 2C, the insulation film 62 such as the silicon oxide film is formed on the trench bottom 105 and the trench sidewall 101 of the trench 63 by a thermal oxidation or the CVD process, for example. The insulation film 62 is deposited at a thickness so as not to close an opening 64 of the trench 63. Therefore, the thickness of the insulation film 62 is determined based on the width of the trench 63. Since the silicon oxide film 60 used as the etching mask during formation of the trench 63 is not removed, the laminated structure of the silicon oxide film 60 and the insulation film 62 is formed on the source region 40 and the base contact diffusion region 50.

In FIG. 3A, the insulation film 62 on the trench bottom 105 of the trench 63 and on the silicon oxide film 60 is etched by an anisotropic etching process, such as RIE. Consequently, the drain region 20 is exposed to the trench 63. The silicon oxide film 60 remains on the source region 40 and the base contact diffusion region 50.

In FIG. 3B, the exposed potion of the drain region 20 is isotropically etched by a dry etching or a wet etching using etchant chemical to form the cave 75 under the trench 63. When the chemical dry etching (CDE) is employed, the drain region 20 is isotropically etched by reactive species due to a chemical reaction. Otherwise, as shown in FIG. 3B, the cave 75 can be formed in the drain region 20 under the trench 63 by anisotropic etching through which a crystalline facet with the inversely tapered shape is exposed.

After the insulation film 62 and the silicon oxide film 60 are removed, the gate insulator 700 shown in FIG. 3C is formed on the trench sidewall 101 of the trench 63 and the cave sidewall 106 of the cave 75. The gate insulator 700 is formed by the thermal oxidation, for example. When the area of the exposed drain region 20 shown in FIG. 3A is appropriate, the cave 75 is formed into the inversely tapered shape. Therefore, an opening of the cave 75 at a boundary between the trench 63 and the cave 75 is sealed with the gate insulator 700 after a given amount of the gate insulator 700 is formed on the trench sidewall 101 of the trench 63 and the cave sidewall 106 of the cave 75. Consequently, as shown in FIGS. 3B-3C, after the gate insulator 700 is formed on the cave sidewall 106 and the cave bottom 107 of the cave 75, the cavity portion 750 is formed in the drain region 20.

After the trench 63 and the cave 75 are separated from each other with the insulation film 700 by sealing the opening 74 of the cave 75, the trench 63 is filled with the electrically conductive material, such as refractory metal or impurity-doped polycrystalline silicon, to form the gate electrode 80. After the gate electrode 80 is formed, the trench-gate structure shown in FIG. 3D is obtained by planarization of the surface of the electrically conductive material.

Further, the interlevel insulator 65 is formed selectively on the gate electrode 80 by the film deposition process such as the CVD process and the photolithography process, for example. Moreover, after portions of the gate insulator 700 are removed, the source electrode layer 55 is further deposited over the interlevel insulator 65, the source region 40, and the base contact diffusion region 50.

According to the method described above, the trench MIS device shown in FIG. 1A is manufactured, where the gate insulator 700 extends via the cavity sidewall 106 of the cavity portion 750 down to the cavity bottom 107 of the cavity portion 750 as shown in FIGS. 3B-3C.

In order to effectively reduce the capacitance (C_{gd}) between the gate electrode 80 and the drain region 20 shown in FIG. 1A, it is important to make the cavity portion 750 large in the direction perpendicular to the drain region 20, namely to design the height of the cavity portion 750 opposite to the gate electrode 80 to be tall. For that purpose, the opening 74 is sealed by the formation of the gate insulator 700 soon after the cave 75 shown in FIG. 3B is formed in the direction perpendicular to the drain region 20 at a sufficient depth. It is important to effectively etch the limited portion of the exposed drain region 20 shown in FIG. 3A. The process parameters for etching the drain region 20 can be determined based on the properties of the insulation film 62, which acts as a stopper for etching at the trench sidewall 101 of the trench 63.

According to the method for manufacturing the trench MIS device in accordance with the first embodiment, the location, the shape, and the size of the cavity portion 750 can be precisely designed and the design can be reflected to the manufacturing of the trench MIS device, and the effect of reducing in the capacitance (C_{gd}) as designed can be achieved.

### Second Embodiment

With reference to FIG. 1B, the trench MIS device in accordance with the second embodiment includes the cavity portion 750 formed by using the surface diffusion of silicon atoms in the drain region 20. The periphery of the cavity portion 750 is defined by a smoothly curved line For example, the periphery of the sectional shape of the cavity portion 750 in the direction perpendicular to the drain region 20 is a round shape, such as an ellipse of which major axis is parallel to the semiconductor substrate 10. Therefore, the shape of the cavity portion 750 is substantially equal to a spheroid. When the cavity portion 750 forms such shape, the electric field is relaxed due to the round shape of the cavity portion 750. Therefore, the withstanding voltage of the trench MIS device in accordance with the second embodiment is stable. The protrusion of the gate electrode 80 into the drain region 20 also effect on the on-state resistance (Rₒₙ) and the capacitance (C_{gd}) as in the case of the first embodiment. The other components of the trench MIS device in accordance with the second embodiment are similar to the components of the device in accordance with the first embodiment. Therefore, such similar components also provide a factorial effect in the second embodiment.

Here, the silicon atoms near the surface of a substrate are diffused and migrated in atomic level by a hydrogen annealing or a high vacuum annealing. Diffusion of the silicon atoms is remarkable near the surface having a large curvature since the silicon atoms tend to minimize the surface energy. Consequently, the surface roughness of the substrate is improved by the hydrogen annealing. Therefore, the hydrogen annealing is used for the planarization of the silicon substrate and forming an SON (Silicon-On-Nothing) structure. In the second embodiment, the hydrogen annealing is applied to form the cavity portion 750. Therefore, in the steps corresponding to FIG. 3A-FIG. 3B, the hydrogen annealing of the cave is performed. By the hydrogen annealing of the cave, the silicon atoms near the surface of the drain region 20 are diffused and the shape of the cave 75 provided in the drain region 20 changes into the broadened shape suitable for reducing the capacitance (C_{gd}).

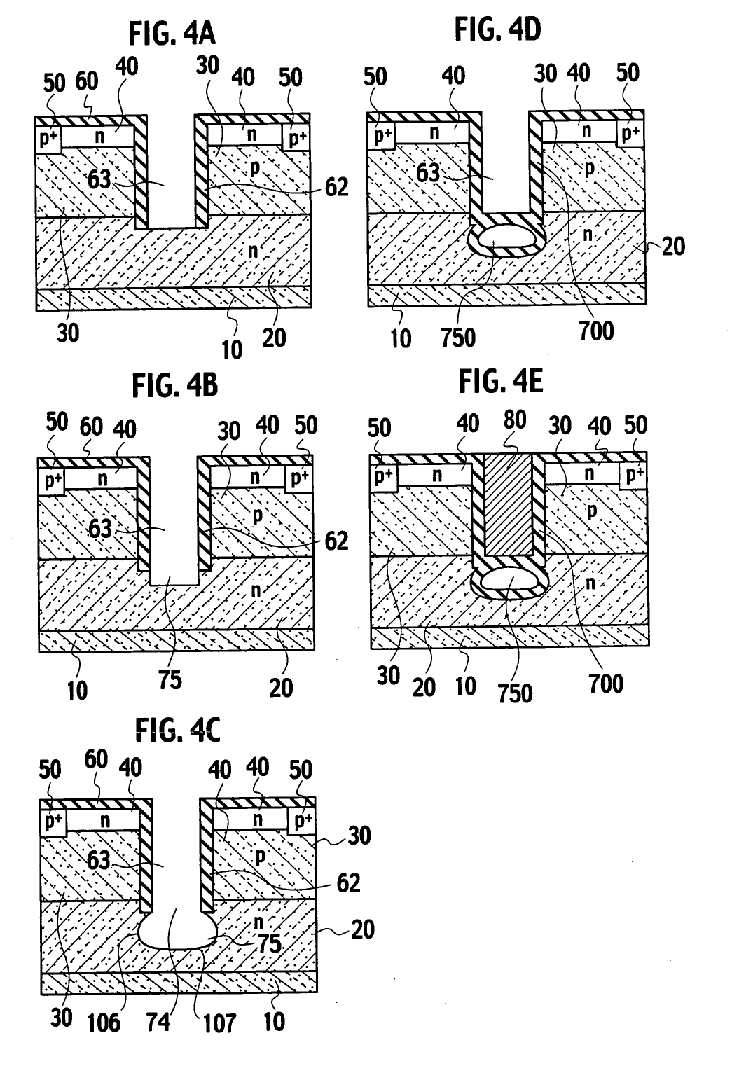

In addition, the shape of the cavity portion 750 after the hydrogen annealing of the cave depends on the shape of the cave 75 shown in FIG. 4B. For example, when the shape of the cave 75 is cylindrical in the direction perpendicular to the drain region 20 and the aspect ratio (a ratio of the depth to a caliber) is large (for example, about 5.5), the nearly middle of the cave 75 is swelled by the hydrogen annealing of the cave. Therefore, the lower portion of the cave 75 is changed to the cavity portion 750 by the hydrogen annealing of the cave as shown in FIGS. 4C-4D. However, if the aspect ratio is too small (for example, about 2.6), the cavity portion 750 is not formed since the cave 75 is filled with the silicon atoms by the surface diffusion. But, when the area of the exposed drain region 20 is small in spite of a small aspect ratio, the opening 74 of cave 75 is closed by the surface diffusion of the silicon atoms and the cavity portion 750 is easy to be formed. Therefore, the process parameters for forming the shape of the cave 75 can be determined so that the cave 75 is not collapsed due to lack of the aspect ratio, for example.

It is not always necessary for the cavity portion 750 to be sealed by the surface diffusion of the silicon atoms caused by the hydrogen annealing of the cave. Also, it is not desirable for the cavity portion 750 to be sealed unintentionally at the early stage of the hydrogen annealing of the cave, resulting in the restriction of the process through which the cavity portion 750 is further broadened. Therefore, the area of the exposed drain region 20 is determined so that the cave 75 spreads out effectively.

In the case where the opening 74 of the cave 75 is already sealed by the surface diffusion of the silicon atoms during the hydrogen annealing of the cave, the cavity portion 750 is already formed when the hydrogen annealing of the cave is completed. Therefore, the gate insulator 700 is only formed on the trench sidewall 101 of the trench 63. Consequently, the cavity portion 750 is substantially defined by the exposed surface of the drain region 20 though the native oxide film may be formed on the exposed surface of the drain region 20. In this case, the inner surface of the cavity portion 750 is not covered with the gate insulator 700 and the cavity portion 750 is provided below the trench bottom of the trench 63. The cavity portion 750 is close to the trench bottom.

With reference to FIGS. 2A-2C and FIGS. 4A-4E, the exampled method for manufacturing the trench MIS device in accordance with the second embodiment is described. The method includes preparing the semiconductor substrate 10 on which the drain region 20, the base region 30, and the source region 40 are formed, forming the trench 63 extending to the drain region 20 through the source region 40 and the base region 30, forming the cave 75 under the trench 63 by etching selectively the drain region 20 exposed at the trench bottom 105 of the trench 63, performing the hydrogen annealing of the cave to broaden the cave 75 by the surface diffusion of the silicon atoms, forming the gate insulator 700 on the trench sidewall 101 of the trench 63 and the cave sidewall 106 of the cave 75 to isolate the trench 63 from the cave 75 with the gate insulator 700, and filling the trench 63 with the electrically conductive material to form the gate electrode 80. In the following, an example of the methods for manufacturing the n-channel transistor is described.

In FIGS. 2A-2C, the trench 63 surrounded with the insulation film 62 is formed as similar to the first embodiment. In FIG. 4A, the insulation film 62 on the trench bottom 105 of the trench 63 is selectively etched by the anisotropic etching such as the RIE and the portion of the drain region 20 is exposed. The silicon oxide film 60 used as the etching mask for forming the trench 63 remains on the source region 40 and the base contact diffusion region 50.

The drain region 20 is anisotropically etched from the exposed portion. Then, the cave 75 is formed under the trench 63 as shown in FIG. 4B. Or, the drain region 20 is isotropically etched from the exposed portion. In this case, the shape of the cave 75 is the flattened sphere, the ellipsoid, or the inversely tapered body as shown in FIG. 3B, which is broadened even in the lateral direction.

In FIG. 4C, the hydrogen annealing of the cave under reduced pressure is performed. The hydrogen annealing of the cave 75 may be performed in a vacuum and at a high temperature. The conditions of the hydrogen annealing of the cave 75 vary depending on the shape, the width, the depth, and even the distance from the adjacent cave of the cave 75. Generally, the conditions such as 100% hydrogen atmosphere, substrate temperature of 1100-1200 degree C., and the treatment period of 10-30 minutes can be used. By the hydrogen annealing of the cave 75, the silicon atoms in the drain region 20 inside the cave sidewall 106 of the cave 75 are diffused. As a result, the corner portions of the cave 75 are rounded. The sectional shape of the cave 75 is changed to the sectional contour defined by the smoothly curved line, which comes to be the origin of the cavity portion 750.

After the insulation film 62 and the silicon oxide film 60 are removed, the gate insulator 700 is formed on the trench sidewall 101 of the trench 63 and the cave sidewall 106 of the cave 75 as shown in FIG. 4D. The gate insulator 700 is formed by the thermal oxidization of the surfaces of the drain region 20, the base region 30, and the source region 40, which define the trench 63 and the cave 75. When the area of the opening 74 is appropriately selected, the opening 74 is sealed with the gate insulator 700 after a given amount of the gate insulator 700 is formed on the trench sidewall 101 of the trench 63 and the cave sidewall 106 of the cave 75, because a diameter of the opening 74 is constricted comparing to a diameter in the middle of the cave 75 after the hydrogen annealing of the cave is performed. Therefore, the gate insulator 700 along the trench sidewall 101 of the trench 63 is formed. Also, the cavity portion 750 of which inner wall is surrounded by the gate insulator 700 is provided.

In FIG. 4E, the trench 63 surrounded with the gate insulator 700 is filled with the electrically conductive material such as the impurity-doped polycrystalline silicon and the refractory metal to form the gate electrode 80. Thereafter, the surface of the gate electrode 80 is planarized and the trench gate structure is obtained.

The interlevel insulator 65 is deposited selectively on the gate electrode 80 by using the film deposition process such as the CVD process and the photolithography, for example. After removing the gate insulator 700 deposited on the source region 40 and the base contact diffusion region 50, the source electrode layer 55 is deposited over the interlevel insulator 65, the source region 40, and the base contact diffusion region 50.

According to the method described above, the trench MIS device shown in FIG. 1B is manufactured. The trench MIS device includes the gate insulator 700 extending via the cavity sidewall 106 of the cavity portion 750 down to the cavity bottom 107 of the cavity portion 750.

In the second embodiment, the cavity portion 750 is formed by the surface diffusion of the silicon atoms caused by the hydrogen annealing of the cave. Therefore, the method for manufacturing the MIS device in accordance with the second embodiment makes it possible to treat the plasma damage at the trench etch with the hydrogen annealing of the cave. Therefore, the trench MIS device can be manufactured without losing the withstanding voltage.

### Third Embodiment

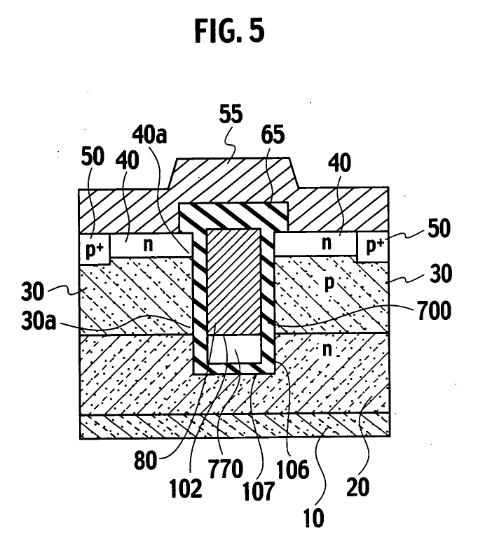

With reference to FIG. 5, the plurality of vertical MOSFETs such as the plurality of trench MIS devices are formed on the semiconductor substrate 10. One of the plurality of trench MIS devices in accordance with the third embodiment includes the semiconductor substrate 10, the drain region 20 on the semiconductor substrate 10, the base region 30 on the drain region 20 having the channel face 30a, the source region 40 on the base region 30 having the source end face 40a which is continuous with the channel face 30a, the gate insulator 700 disposed continuously along the channel face 30a and the source end face 40a, the gate electrode 80 provided opposite to the channel face 30a so that the gate insulator 700 is interposed between the gate electrode 80 and the channel face 30a, and the cavity portion 770 provided opposite to the gate electrode 80 in the drain region 20 under the gate electrode 80. Polycrystalline silicon can be used for the gate electrode 80. The interlevel insulator 65 is disposed on the gate electrode 80. The source electrode layer 55 is disposed on the source region 40 and the base contact diffusion region 50. The drain electrode, not shown in the figure, is formed on the rear surface of the semiconductor substrate 10.

In the trench MIS device according to the third embodiment, the gate insulator 700 extends via the cavity sidewall 106 of the cavity portion 770 down to the cavity bottom 107 of the cavity portion 770. However, the gate insulator 700 does not extend to the electrode bottom 102 of the gate electrode 80. Therefore, the cavity portion 770 is provided in contact with the gate electrode 80 directly under the gate electrode 80. The cavity sidewall 106 and the cavity bottom 107 of the cavity portion 770 are covered with the gate insulator 700. In the case where the trench MIS device is the n-channel transistor, for example, the drain region 20, the base region 30, and the source region 40 are respectively the n-type, the p-type, and the n-type.

The cavity portion 770 increases the distance between the drain region 20 and the gate electrode 80. As described above, the relative dielectric constant in the cavity portion 770 is small. Therefore, the cavity portion 770 reduces the capacitance (C_{gd}) by 50%. The trench MIS device has similar factorial effects as the devices according to the first and second embodiments.

In the third embodiment, the gate insulator 700 is formed along the trench sidewall and the trench bottom. The electrode bottom 102 of the gate electrode 80 directly faces the cavity portion 770. The all area of the electrode bottom 102 in a direction to the drain region 20 substantially faces the cavity portion 770. Since the relative dielectric constant in the cavity portion 770 is smaller than the relative dielectric constant of the gate insulator 700, the capacitance (C_{gd}) is effectively reduced. Therefore, a difficulty of designing the transistor is reduced when the semiconductor devices are designed based on each electrical characteristic of the transistors.

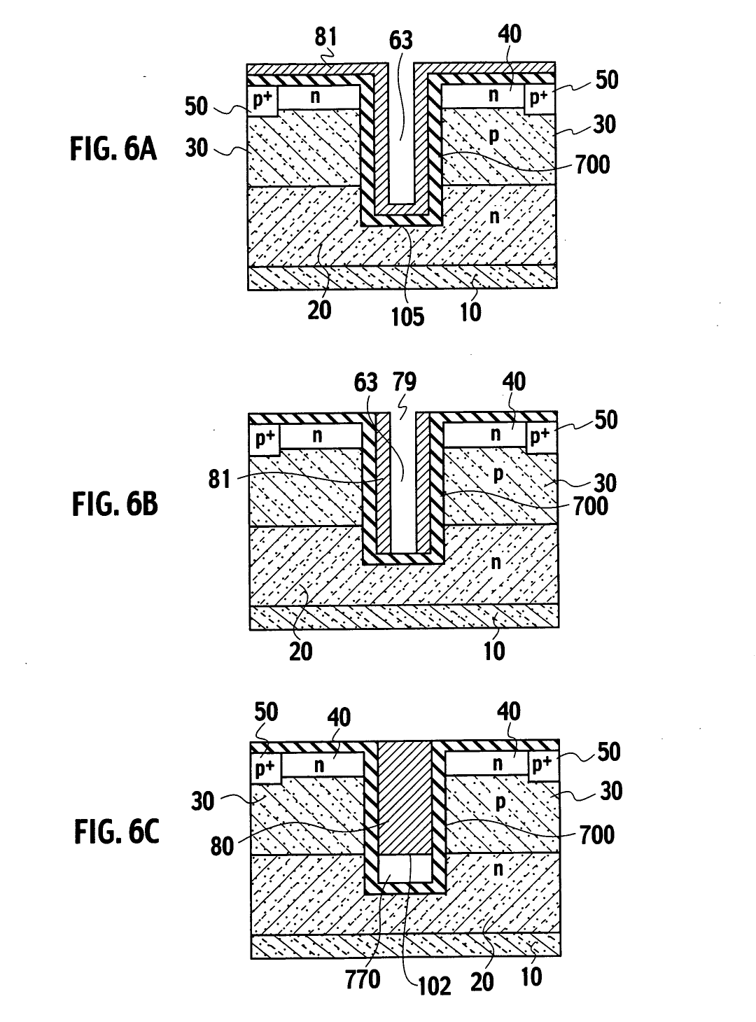

With reference to FIGS. 2A-2C and FIGS. 6A-6C, the method for manufacturing the trench MIS device in accordance with the third embodiment is described. The method includes preparing the semiconductor substrate 10 on which the drain region 20, the base region 30, and the source region 40 are formed in this order, forming the trench 63 extending to the drain region 20 through the source region 40 and the base region 30, depositing the gate insulator 700 on the trench sidewall 101 of the trench 63, depositing the polycrystalline silicon film 81 on the trench sidewall 101 of the trench 63 so that the trench 63 is not fully filled with the polycrystalline silicon film 81, performing the hydrogen annealing of the polycrystalline silicon film to diffuse the silicon atoms in the polycrystalline silicon film 81, and forming the cavity portion 770 at the lower portion of the trench 63 and the gate electrode 80 above the cavity portion 770. In the following, an example of the method for manufacturing the n-channel transistor is described.

The n-type drain region 20, the p-type base region 30, and the n-type source region 40 is formed on the semiconductor substrate 10. Then, the source region 40 is, as shown in FIG. 2A, selectively formed together with the p⁺-type base contact diffusion region 50 on the base region 30.

In FIG. 2B, the silicon oxide film 60 is deposited on the surfaces of the source region 40 and the base contact diffusion region 50 and selectively etched using the etched silicon oxide film 60 as the etching mask, as shown in FIG. 2B, the trench 63 extending to the drain region 20 is formed. Further, a part of the drain region 20 is removed by a reactive ion etching (RIE), for example. It should be noted that the trench 63 according to the third embodiment is deeper than the trench 63 according to the first embodiment, since the cavity portion 770 will be formed in the lower portion of the trench 63.

After the silicon oxide film 60 is removed, the gate insulator 700 is formed on the source region 40, the base contact diffusion region 50, and the trench sidewall 101 of the trench 63 as shown in FIG. 6A. The gate insulator 700 is formed by the thermal oxidation.

The polycrystalline silicon film 81 that is a precursor of the gate electrode 80 is deposited on the surface of the substrate including the gate insulator 700. The polycrystalline silicon film 81 is doped with the plurality of dopants. The polycrystalline silicon film 81 is formed so that the trench 63 is not fully filled with the polycrystalline silicon film 81.

In FIG. 6B, portions of the polycrystalline silicon film 81 on the trench bottom 105 of the trench 63, the source region 40, and the base contact diffusion region 50 is selectively removed by using the anisotropic etching such as the RIE. Therefore, portions of the gate insulator 700 on the trench bottom 105 of the trench 63, the source region 40, and the base contact diffusion region 50 are exposed. Accordingly, the polycrystalline silicon film 81 remains on the trench sidewall 101 of the trench 63. The polycrystalline silicon film 81 extends from the gate insulator 700 on the trench bottom 105 to the opening 79.

In FIG. 6C, the hydrogen annealing of the polycrystalline silicon film 81 is performed to diffuse the silicon atoms in the polycrystalline silicon film 81. Consequently, the polycrystalline silicon film 81 is segregated to the upper portion of the trench 63 and the cavity portion 770 is formed in the lower portion of the trench 63 by the surface diffusion of the silicon atoms.

The hydrogen annealing of the polycrystalline silicon film 81 is performed at the high temperature and under the reduced pressure. The hydrogen annealing of the polycrystalline silicon film 81 may be performed in the vacuum. The conditions of the hydrogen annealing of the polycrystalline silicon film 81 vary depending on the size and the shape of the polycrystalline silicon film 81, and the aspect ratio defined by the bore versus the depth of the trench 63. Generally, the conditions such as 100% hydrogen atmosphere, the substrate temperature of 1100-1200 degree C., and the treatment period of 10-30 minutes can be used for the hydrogen annealing of the polycrystalline silicon film 81.

Through the hydrogen annealing of the polycrystalline silicon film 81, the silicon atoms in the polycrystalline silicon film 81 are diffused near the surface of the polycrystalline silicon film 81. By the surface diffusion, the silicon atoms tend to minimize the surface energy. Therefore, the opening 79 shown in FIG. 6B is closed by surface diffusion of the silicon atoms and the cavity portion 770 FIG. 6C is formed in the drain region 20. Consequently, the electrode bottom 102 of the gate electrode 80 derived from the polycrystalline silicon film 81 faces to the cavity portion 770.

Thereafter, the interlevel insulator 65 is deposited selectively on the gate electrode 80 by using the film deposition process such as the CVD process and the photolithography process, for example. Moreover, after portions of the gate insulator 700 on the source region 40 and the base contact diffusion region 50 are removed, the source electrode layer 55 is deposited on the interlevel insulator 65, the source region 40, and the base contact diffusion region 50.

According to the method described above, the trench MIS device shown in FIG. 5 is manufactured. The trench MIS device shown in FIG. 5 has the gate insulator 700 extending via the cavity sidewall 106 of the cavity portion 770 down to the cavity bottom 107 of the cavity portion 770. The method according to the third embodiment is effective to form the cavity portion 770 between the electrode bottom 102 of the gate electrode 80 and the gate insulator 700 disposed on the cavity bottom 107 of the cavity portion 770.

### Fourth Embodiment

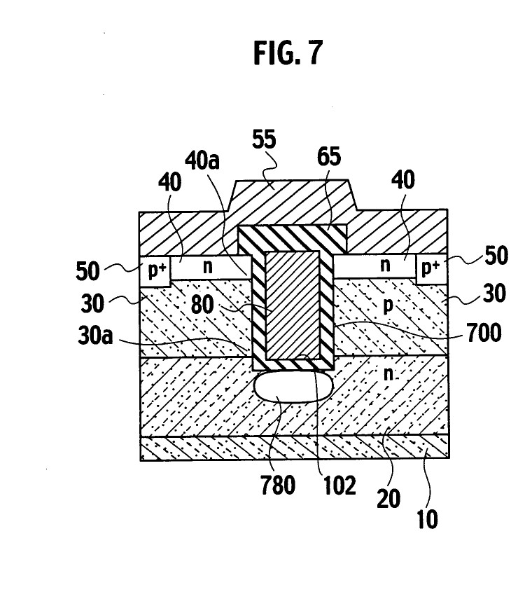

With reference to FIG. 7, the plurality of vertical MOSFETs such as the plurality of trench MIS devices are formed on the semiconductor substrate 10. The trench MIS device in accordance with the fourth embodiment includes the semiconductor substrate 10, the drain region 20, the base region 30 on the drain region 20 having the channel face 30a, the source region 40 on the base region 30 having the source end face 40a which is continuous with the channel face 30a, the gate insulator 700 disposed continuously along the channel face 30a and the source end face 40a, the gate electrode 80 disposed opposite to the channel face 30a so that the gate insulator 700 is interposed between the channel face 30a and the gate electrode 80, and the cavity portion 780 provided opposite to the gate electrode 80 within the drain region 20 under the gate electrode 80. The interlevel insulator 65 is disposed on the gate electrode 80. The source electrode layer 55 is disposed on the source region 40 and the base contact diffusion region 50. The drain electrode, not shown in the figure, is formed on the rear surface of the semiconductor substrate 10.

In the trench MIS device in accordance with the fourth embodiment, the gate insulator 700 extends to a portion between the electrode bottom 102 of the gate electrode 80 and the upper potion of the cavity portion 780. The cavity portion 780 is provided under the gate insulator 700 disposed on the electrode bottom 102 of the gate electrode 80. In the case where the trench MIS device is the n-channel transistor, for example, the drain region 20, the base region 30, and the source region 40 are respectively the n-type, the p-type, and the n-type.

The cavity portion 780 increases the distance between the drain region 20 and the gate electrode 80 in the direction perpendicular to the drain region 20. As described above, the relative dielectric constant in the cavity portion 780 is one third of the relative dielectric constant of the gate insulator 700. Therefore, the cavity portion 780 reduces the capacitance (C_{gd}). The trench MIS device has similar factorial effects as the devices according to the first to third embodiments.

The method for manufacturing the trench MIS device in accordance with the fourth embodiment applies the surface diffusion of the silicon atoms caused by the hydrogen annealing of the cave to provide the cavity portion 780 in the drain region 20 before the trench 63 is provided in the base region 30. The hydrogen annealing is performed in vacuum and at the high temperature. Thereafter, the trench 63 corresponding to the gate of the transistor is formed above the cavity portion 780.

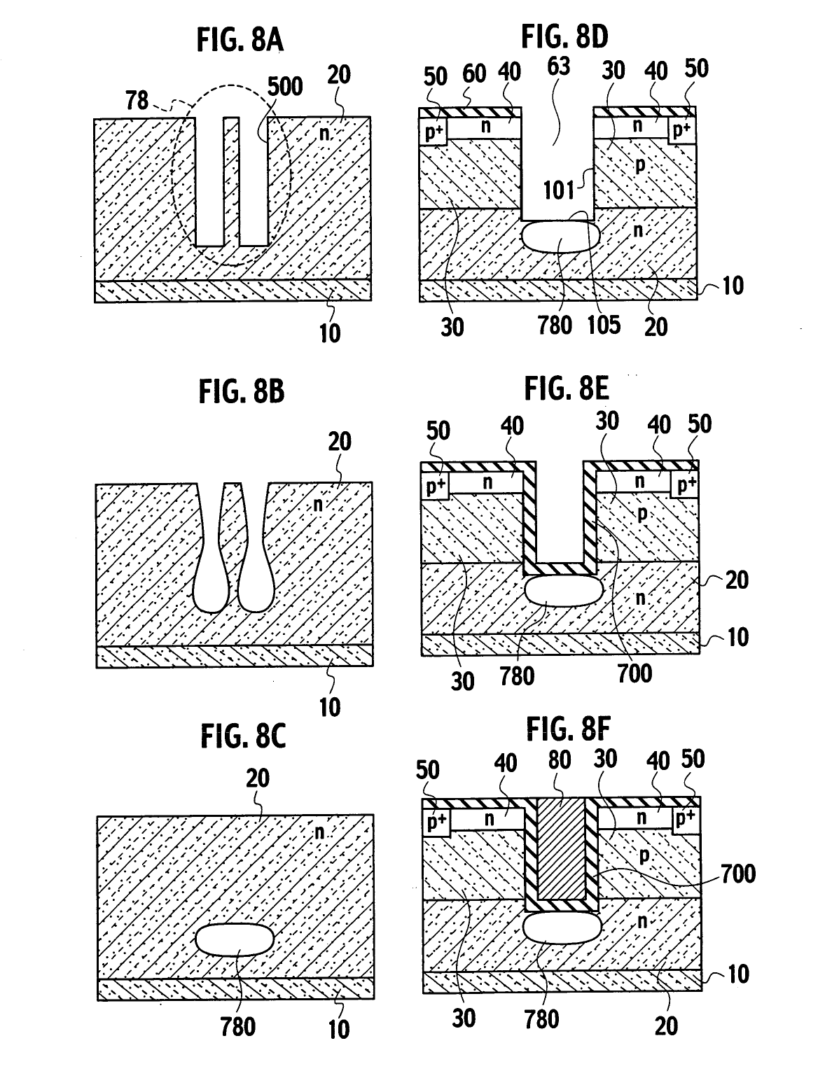

With reference to FIGS. 8A-8F, the method includes forming a single cave or a plurality of caves 78 in the drain region 20 formed on the semiconductor substrate 10, performing the hydrogen annealing of the cave to form the cavity portion 780 by the surface diffusion of the silicon atoms in the drain region 20, forming the trench 63 in the base region 30 and the drain region 20 above the cavity portion 780, forming the gate insulator 700 on the trench sidewall 101 of the trench 63 by the thermal oxidization, filling the trench 63 with the electrically conductive material to form the gate electrode 80. In the following, an example of the method for manufacturing the n-channel transistor is described.

In FIG. 8A, the semiconductor substrate 10 on which the drain region 20 is formed is prepared. The drain region 20 is formed by the epitaxial growth process performed on the substrate 10 as similar to the first embodiment. Thereafter, the single cave or the plurality of caves 78 are formed in the drain region 20 to form the cavity portion 780. FIG. 8A shows the case where the two caves 78 are formed adjacent to each other. The two caves 78 are formed by the anisotropic etching such as the RIE, for example.

The hydrogen annealing of the cave is performed at the high temperature and under the reduced pressure for the substrate 10 with the drain region 20 having the caves 78. The conditions of the hydrogen annealing of the cave are 100% hydrogen atmosphere, the substrate temperature of 1100-1200 degree C., and the treatment period of 10-30 minutes, for example. As described in the second embodiment, by the hydrogen annealing of the cave, the silicon atoms inside each cave sidewall 500 of the caves 78 in the drain region 20 are diffused. Therefore, as shown in FIG. 8B, each shape of the caves 78 is changed into the shape which is constricted in the middle and has a tinge of swelling at the end portion.

When the distance between each of the plural caves 78 is smaller than or equal to a given value, each of the plural caves 78 comes into contact with each other at the swelled portion. In FIG. 8C, the integrated cavity portion 780 that is sealed at the constricted central portion is formed in the drain region 20.

In FIG. 8D, the p-type base region 30, the n-type source region 40, and the p⁺-type base contact diffusion region 50 are formed on the n-type drain region 20. Methods for forming the p-type base region 30, the n-type source region 40, and the p⁺-type base contact diffusion region 50 are similar to the first embodiment. Then, the trench 63 is delineated in the source region 40 and the base region 30. The trench 63 is formed by the anisotropic etching process such as the RIE using the silicon oxide film 60 as the etching mask. The trench 63 is formed so that a thin membrane of the drain region 20 remains between the trench bottom 105 of the trench 63 and the upper portion of the cavity portion 780. Therefore, the trench 63 is prevented from penetrating the thin membrane above the cavity portion 780.

After the silicon oxide film 60 is removed, the gate insulator 700 is formed on the trench sidewall 101 of the trench 63 and the surfaces of the source region 40 and the base contact diffusion region 50 as shown in FIG. 8E. The gate insulator 700 is formed by the thermal oxidation. By the thermal oxidation, the thin membrane of the drain region 20 above the cavity portion 780 is also changed into the gate insulator 700.

In FIG. 8F, the trench 63 is filled with the electrically conductive material such as the polycrystalline silicon doped with impurities and the refractory metal to form the gate electrode 80 on the gate insulator 700. Thereafter, the surface of the gate electrode 80 is planarized. Accordingly, the trench gate structure with the cavity portion 780 is obtained.

The interlevel insulator 65 is deposited selectively on the gate electrode 80 by the film deposition process such as the CVD process and the photolithography process, for example. After the portions of the gate insulator 700 on the n-type source region 40 and the p⁺-type base contact diffusion region 50 are removed, the source electrode layer 55 is deposited over the interlevel insulator 65, the source region 40, and the base contact diffusion region 50.

According to the methods described above, the trench MIS device shown in FIG. 7 is manufactured. The trench MIS device has the gate insulator 700 extending between the cavity portion 780 and the gate electrode 80.

By the method in accordance with the fourth embodiment, the trench MIS device having the cavity portion 780 under the trench bottom 105 of the trench 63 is effectively manufactured.

In the case where the cavity portion 780 is formed by the surface diffusion of the silicon atoms, although precise dimensional tolerances of the cavity portion 780 and precise positional tolerances of the trench 63 relative to the cavity portion 780 above which the trench 63 is formed are required, the process parameters can be determined through investigating the conditions of the hydrogen annealing of the cave and the etching conditions.

### Fifth Embodiment

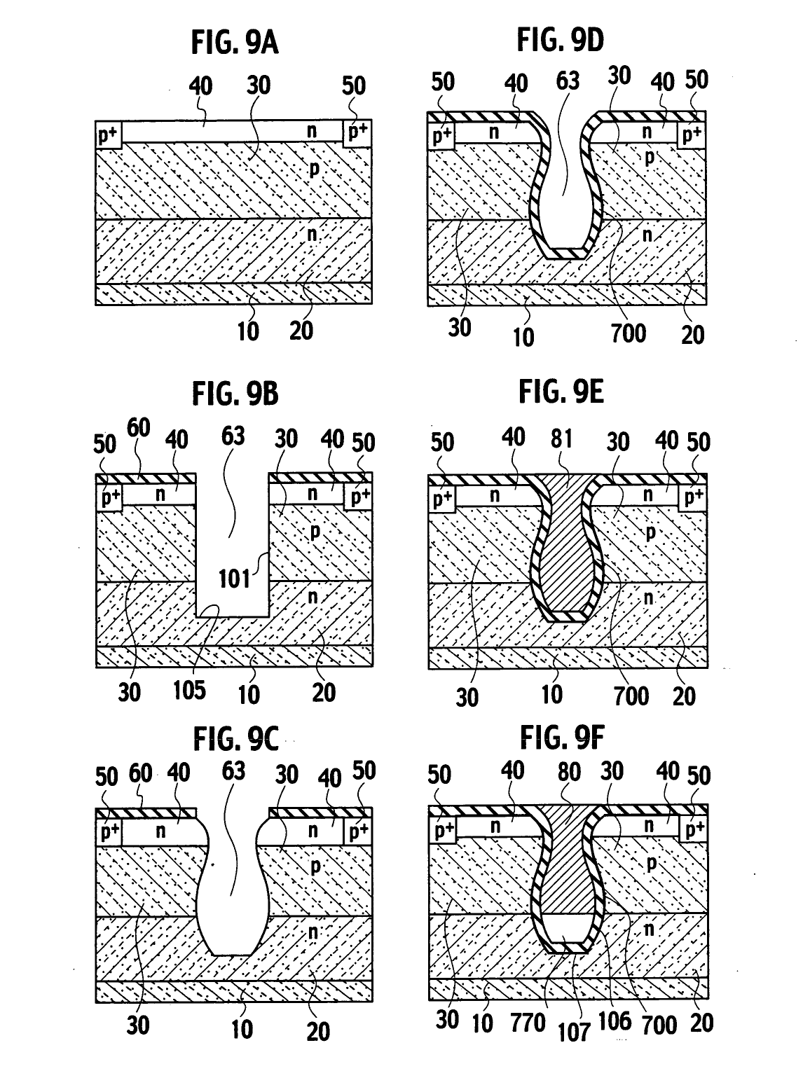

With reference to FIG. 9F, the trench MIS device in accordance with the fifth embodiment includes the cavity portion 770 formed in the drain region 20. The electrode bottom of the gate electrode 81 is exposed to the cavity portion 770. In the fifth embodiment, the channel face of the base region 30, the source end face of the source region 40, and the cavity sidewall 106 of the cavity portion 770 define the trench sidewall. The cavity bottom 107 of the cavity portion 770 defines the trench bottom. Here, the trench having the trench sidewall and the trench bottom establishes the constricted shape. Therefore, the shape of the gate electrode 81 in accordance with the fifth embodiment is constricted in the vicinity of the middle of the gate electrode 81. Since the shape of gate electrode 81 is constricted in the middle and swelled at the lower portion, the electric field between the gate electrode 80 and the drain region 20 is relaxed. Therefore, the withstanding voltage of the trench MIS device is improved.

With reference to FIGS. 9A-9F, the method for manufacturing the trench MIS device is described. The method applies the surface diffusion of the silicon atoms to change the shape of the trench 63 as shown in FIGS. 9B-9C. The trench 63 is filled with the gate-electrode material such as the polycrystalline silicon film 81 and the polycrystalline silicon film 81 that is a precursor of the gate electrode 80 is annealed. By the annealing, a number of voids are formed in the polycrystalline silicon film 81. By segregating the numerous voids to the lower portion of the trench 63, the cavity portion 770 is formed in the drain region 20.

The method for manufacturing the trench MIS device in accordance with the fifth embodiment includes preparing the semiconductor substrate 10 on which the drain region 20, the base region 30, and the source region 40 are formed, forming the trench 63 extending to the drain region 20 through the source region 40 and the base region 30, performing the hydrogen annealing of the trench 63 to constrict the trench 63 in the middle and swell the trench 63 at the lower portion, forming the gate insulator 700 on the trench sidewall 101 of the trench 63, filling the trench 63 with the polycrystalline silicon film 81, performing the hydrogen annealing of the polycrystalline silicon film 81 to form the cavity portion 770 at the lower portion of the trench 63 by the segregation of the voids generated in the polycrystalline silicon film 81 and to form the gate electrode 80 above the cavity portion 770.

In the following, an example of the method for manufacturing the n-channel transistor is described.

In FIG. 9A, the silicon semiconductor substrate 10 on which the n-type drain region 20, the p-type base region 30, and the n-type source region 40 are formed is prepared. The methods for forming the n-type drain region 20, the p-type base region 30, and the n-type source region 40 are similar to the first embodiment.

In FIG. 9B, the silicon oxide film 60 is deposited on the surfaces of the source region 40 and the base contact diffusion region 50 by the thermal oxidation or the CVD process, for example. Then, the silicon oxide film 60 is selectively etched. Thereafter, the n-type source region 40, the base region 30, and the drain region 20 are selectively etched by using the etched silicon oxide film 60 as the etching mask to form the trench 63. The reactive ion etching (RIE) process is applied to form the trench 63, for example.

In FIG. 9C, the hydrogen annealing of the trench is performed to change the shape of the trench 63. The conditions of the hydrogen annealing of the trench 63 vary depending on the shape, the width, and the depth of the trench 63. For example, 100% hydrogen atmosphere, the substrate temperature of 900-1000 degree C., and treatment period of one to five minutes are employed as the conditions. By the hydrogen annealing of the trench, the silicon atoms are diffused near the surfaces of the source region 40, the base region 30, and the drain region 20. By the surface diffusion, the silicon atoms tend to minimize the surface energy of the trench sidewall 101 of the trench 63. When the trench 63 is cylindrical, the trench bottom 105 and the opening of the trench 63 have relatively large curvatures. By the hydrogen annealing of the trench 63, the silicon atoms move toward the trench bottom 105 and the opening of the trench 63. Therefore, the trench 63 is constricted in the middle and swelled at the lower portion.

After the silicon oxide film 60 is removed, the gate insulator 700 is formed on the trench sidewall 101 of the trench 63 as shown in FIG. 9D. The gate insulator 700 is formed by the thermal oxidation.

In FIG. 9E, the trench 63 is filled with the doped polycrystalline silicon film 81. The doped polycrystalline silicon film 81 is deposited on the gate insulator 700 by the film deposition process such as the CVD process. Since the trench 63 of which trench sidewall 101 is surrounded by the gate insulator 700 is constricted, the trench 63 is heterogeneously filled with the doped polycrystalline silicon film 81. Therefore, the voids are formed in the polycrystalline silicon film 81. The smaller the caliber of the trench 63 is, the more the voids are formed. Also, the more the trench 63 is constricted, the more the voids are formed.

After the trench 63 is filled with the polycrystalline silicon film 81, the hydrogen annealing of the polycrystalline silicon film 81 is performed. By the hydrogen annealing of the polycrystalline silicon film 81, the voids formed in the polycrystalline silicon film 81 are segregated to the lower portion of the trench 63, since the voids tend to minimize the surface energy. In this case, the polycrystalline silicon film 81 is annealed at 900-1000 degree C.

In FIG. 9F, the segregated voids form the cavity portion 770. Therefore, the gate electrode 80 is exposed to the cavity portion 770. FIG. 9F shows the case where the cavity portion 770 is formed in the lower portion of the trench 63. However, the position of the cavity portion 770 is not limited to the trench bottom 105 of the trench 63. For example, the cavity portion 770 may be formed in the middle of the trench 63. In this case, residual of the polycrystalline silicon film 81 remains on the trench bottom 105 of the trench 63. However, such residual does not implement as the gate electrode 80 since the residual is not electrically connected to the gate electrode 80 above the cavity portion.

After the cavity portion 770 is formed, the interlevel insulator 65 is deposited selectively on the gate electrode 80 by the film deposition process such as the CVD process and the photolithography, for example. After the portions of the gate insulator 700 on the n-type source region 40 and the base contact diffusion region 50 are removed, the source electrode layer 55 is deposited over the interlevel insulator 65, the source region 40, and the base contact diffusion region 50.

According to the method mentioned above, the trench MIS device having the gate insulator 700 extending via the cavity sidewall 106 of the cavity portion 770 down to the cavity bottom 107 of the cavity portion 770 is manufactured.

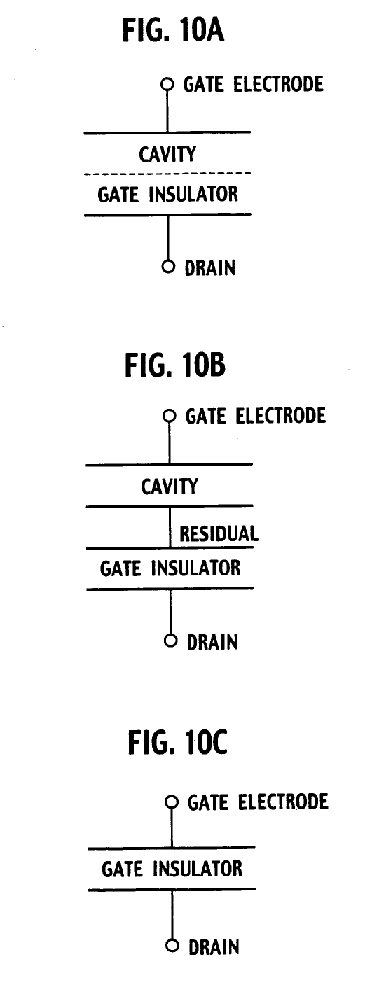

FIGS. 10A-10C show circuits between gates and drains. In the earlier trench MIS device, the cavity portion is not provided under the gate electrode. Therefore, as shown in FIG. 10C, the gate electrode, the gate insulator, and the drain region implement the capacitance (C_{gd}). On the contrary, the trench MIS device in accordance with the fifth embodiment shown in FIG. 9F includes the drain region 20 having the cavity portion 770. Therefore, as shown in FIG. 10A, the gate electrode 80, the gate insulator 700, and the drain region 20 implement the capacitance (C_{gd}) and the capacitance is reduced by the cavity portion 750. When the cavity potion 750 is formed in the middle of of the trench 63, the residual of the polycrystalline silicon film 81 remains on the trench bottom 105 of the trench 63 as described above. Therefore, as shown in FIG. 10B, the gate electrode 80, the cavity portion 770, and the residual implement a first capacitance. Also, the residual, the gate insulator 700, and the drain region 20 implement a second capacitance. However, there is no substantial difference between the electrostatic capacitances of the circuits shown in FIGS. 10A and 10B.

It should be noted that the cavity portion 770 is formed in the drain region 20. If the cavity portion 770 is formed in the base region 30, the device does not behave well, since the gate voltage is reduced by the cavity portion 770. Therefore, the channel is not formed well when the cavity portion 770 is formed in the base region 30.

Further, the present invention is not limited to the above embodiments and can be worked in an appropriate modification within the scope not exceeding the gist of the present invention. For example, in each embodiment, the MOSFET with the trench-gate is described. However, these embodiments can be applied also to other semiconductor devices such as the IGBT and the IEGT having the trench-gate structure.

What is claimed is:

1. A trench MIS device comprising:
a drain region;
a base region disposed on the drain region, the base region having a channel face;
a source region disposed on the base region, the source region having a source end face, the source end face being continuous with the channel face;
a gate insulator disposed continuously along the channel face and the source end face;
a gate electrode disposed opposite to the channel face through the gate insulator; and
a cavity portion provided in the drain region below the gate electrode, the cavity portion being opposite to the gate electrode.

2. The device of claim 1, wherein the gate insulator extends to a cavity bottom of the cavity portion from the channel face and the source end face via a cavity sidewall of the cavity portion.

3. The device of claim 2, wherein the channel face, the source end face, and the cavity sidewall of the cavity portion define a trench sidewall, the cavity bottom of the cavity portion defines a trench bottom, and a trench having the trench sidewall and the trench bottom establishes a constricted shape in a middle portion.

4. The device of claim 1, wherein the gate insulator extends to a portion between the cavity portion and the gate electrode.

5. The device of claim 4, wherein the gate insulator extends to an inner wall of the cavity portion.

6. The device of claim 1, wherein a sectional contour of the cavity portion is defined by a curved line.

7. The device of claim 1, the cavity portion has an inversely tapered shape, the inversely tapered shape broadening at a cavity bottom of the cavity portion.

8. A method for manufacturing a trench MIS device including:
preparing a semiconductor substrate on which a drain region, a base region, and a source region are formed in order;
forming a trench extending from the source region to the drain region via the base region, the trench having a trench sidewall and a trench bottom;
forming a gate insulator on the trench sidewall and the trench bottom;
forming a polycrystalline silicon film on the gate insulator, the polycrystalline silicon film being doped with a plurality of dapants; and
forming a cavity portion in a lower portion of the trench and a gate electrode derived from the polycrystalline silicon film in an upper portion of the trench by a diffusion of a plurality of silicon atoms in the polycrystalline silicon film, the diffusion being caused by a hydrogen annealing of the polycrystalline silicon film.

9. The method of claim 8, further including removing a portion of the polycrystalline silicon film formed on the gate insulator disposed on the trench bottom of the trench before the hydrogen annealing of the polycrystalline silicon film.

10. The method of claim 9, wherein an anisotropic etching is employed to remove the portion of the polycrystalline silicon film.

11. The method of claim 9, wherein the hydrogen annealing of the polycrystalline silicon film is performed in a reduced pressure.

12. The method of claim 9, wherein the hydrogen annealing of the polycrystalline silicon film is performed at 1100 to 1200 degree C. for 10 to 30 minutes.

13. The method of claim 8, further including changing a shape of the trench by a diffusion of a plurality of silicon atoms inside the trench sidewall by a hydrogen annealing of the trench before the gate insulator is formed.

14. The method of claim 13, wherein the trench is filled with the polycrystalline silicon film via the gate insulator after the hydrogen annealing of the trench and a plurality of voids in the polycrystalline silicon film is segregated to form the cavity portion by the hydrogen annealing of the polycrystalline silicon film.

15. The method of claim 13, wherein a sectional contour of the trench defined by the trench sidewall has a constricted shape after the hydrogen annealing of the trench.

16. The method of claim 15, wherein the hydrogen annealing of the trench is performed at 900 to 1000 degree C. for one to five minutes.

17. A method for manufacturing a trench MIS device including:
forming a drain region on a semiconductor substrate;
forming a cave in the drain region;
diffusing a plurality of silicon atoms inside a cave sidewall of the cave by a hydrogen annealing of the cave so as to fill an upper portion of the cave with the silicon atoms to form a cavity portion in the drain region;
forming a trench above the cavity portion in the drain region, the trench being not penetrating to the cavity portion;
forming a gate insulator on a trench sidewall of the trench; and
forming a gate electrode on the gate insulator by filling the trench with an electrically conductive material.

18. The method of claim 17, further including doping a plurality of dopants into the drain region to provide a base region and a source region on the drain region after the cavity portion is formed.

19. The method of claim 17, wherein the hydrogen annealing of the cave is performed in a reduced pressure.

20. The method of claim 17, wherein the hydrogen annealing of the cave is performed at 1100 to 1200 degree C. for 10 to 30 minutes.
